(19) United States
(12) Patent Application Publication
(10) Pub. No.: US 2011/0221098 A1
(43) Pub. Date: Sep. 15, 2011

(54) METHODS OF MANUFACTURING ALIGNMENT SUBSTRATE AND LIQUID CRYSTAL DISPLAY DEVICE HAVING THE ALIGNMENT SUBSTRATE

(75) Inventors: Won-Sang PARK, Yongin-City (KR); Kee-Han UH, Yongin-City (KR); Sin-Doo LEE, Seoul (KR); Jun-Hee NA, Seoul (KR); Yeun-Tae KIM, Suwon-si (KR); Kyung-Mo KOO, Seoul (KR)

(73) Assignees: SAMSUNG MOBILE DISPLAY CO., LTD., Yongin-City (KR); SEOUL NATIONAL UNIVERSITY R&DB FOUNDATION, Seoul (KR)

(21) Appl. No.: 13/044,440

(22) Filed: Mar. 9, 2011

(30) Foreign Application Priority Data
Mar. 11, 2010 (KR) 10-2010-0021841

(51) Int. Cl. C30B 33/08; B29C 35/08

(52) U.S. Cl. 264/400; 264/293; 216/23

(57) ABSTRACT

A method of manufacturing an alignment substrate includes preparing a first substrate on which an alignment film aligned in a first alignment direction is formed; forming a plurality of fluoro-polymer patterns on the first substrate; changing the alignment direction of regions of the alignment film on which the fluoro-polymer patterns are not formed; and removing the fluoro-polymer patterns by using a fluoro-solvent.

### CLAIM OF PRIORITY

This application makes reference to, incorporates the same herein, and claims all benefits accruing under 35 U.S.C. §119 from an application earlier filed in the Korean Intellectual Property Office on the 11^{th} of March 2010 and there duly assigned Serial No. 10-2010-0021841.

### BACKGROUND OF THE INVENTION

1. Field of the Invention

Embodiments of the present invention relate to a method of manufacturing an alignment substrate and a method of manufacturing a liquid crystal display device having the alignment substrate, and more particularly, to a method of manufacturing an alignment substrate on which multiple alignment films are formed, and to a method of manufacturing a multi-domain liquid crystal display (LCD) device having the alignment substrate.

2. Description of the Related Art

A liquid crystal display (LCD) device is an image display device that displays images by controlling optical transmittance of light by applying a voltage to a liquid crystal layer interposed between an array substrate on which a pixel electrode is formed and a face substrate on which a common electrode is formed.

Among the liquid crystal display devices, a twisted nematic (TN) mode liquid crystal display device has advantages such as a higher optical transmittance, shorter response times and a simpler manufacturing process.

Recently, since the size of display devices increases, issues related to side visibility and viewing angle of the display devices become more significant. Therefore, interest in a multiple alignment technique of the TN mode liquid crystal display device has increased.

### SUMMARY OF THE INVENTION

In order to solve the above and/or other problems, an embodiment of the present invention provides a method of manufacturing an alignment substrate on which multiple alignment films are formed, and a method of manufacturing a multi-domain liquid crystal display (LCD) device having the alignment substrate.

It is therefore one aspect of the present invention to provide an improved method of manufacturing an alignment substrate. The method may include steps of (a) preparing a first substrate on which an alignment film aligned in a first alignment direction is formed; (b) forming a plurality of fluoro-polymer patterns on the first substrate; (c) changing the alignment direction of regions of the alignment film on which the fluoro-polymer patterns are not formed; and (d) removing the fluoro-polymer patterns by using a fluoro-solvent.

In operation (b), the fluoro-polymer patterns may be formed by transferring the fluoro-polymer patterns formed on a stamping mold onto the first substrate.

The stamping mold may be a polydimethysiloxane (PDMS) mold.

In operation (b), after a fluoro-polymer layer is formed on the first substrate, the fluoro-polymer patterns may be formed on the first substrate by using a laser ablating method.

In operation (b), the fluoro-polymer patterns may be spaced apart from each other with a predetermined distance.

In operation (c), the alignment direction of the alignment film on which the fluoro-polymer patterns are not formed may be changed to a second alignment direction opposite to the first alignment direction.

In operation (c), the alignment film aligned in the first alignment direction may have the same area as the alignment film aligned in the second alignment direction.

In operation (c), the alignment direction of the alignment film may be changed by using a rubbing method.

In operation (c), the alignment direction of the alignment film may be changed by using a photo-alignment method.

It is another aspect of the present invention to provide a method of manufacturing an alignment substrate, and the method may include steps of (a) preparing a first substrate on which an alignment film aligned in a first alignment direction is formed; (b) forming a plurality of fluoro-polymer patterns on the first substrate; (c) changing the alignment direction of regions of the alignment film on which the fluoro-polymer patterns are not formed; (d) removing the fluoro-polymer patterns by using a fluoro-solvent; (e) preparing a second substrate having multiple alignment directions which are different from each other and are alternately disposed in the second substrate by performing operations (a) through (d) described above; and (f) combining the first substrate and the second substrate so that the alignment directions of the first substrate and the second substrate cross each other, and injecting liquid crystal between the first substrate and the second substrate.

In operation (b), the fluoro-polymer patterns may be formed by transferring the fluoro-polymer patterns formed on a stamping mold onto the first substrate.

In operation (b), after a fluoro-polymer layer is formed on the first substrate, the fluoro-polymer patterns may be formed on the first substrate by using a laser ablating method.

In operation (b), the fluoro-polymer patterns may be spaced apart from each other by a predetermined distance.

The stamping mold may be a polydimethysiloxane (PDMS) mold.

In operation (c), the alignment direction of the alignment film on which the fluoro-polymer patterns are not formed may be changed to a second alignment direction opposite to the first alignment direction.

In operation (c), the alignment film aligned in the first alignment direction may have the same area as the alignment film aligned in the second alignment direction.

In operation (c), the alignment direction of the alignment film may be changed by using a rubbing method.

In operation (c), the alignment direction of the alignment film may be changed by using a photo-alignment method.

In operation (e), the alignment films formed on the second substrate may have multiple alignment directions opposite to each other.

In the operation of (e), the alignment films having alignment directions opposite to each other may have the same area.

In operation (f), the first substrate and the second substrate may be combined so that the alignment directions of the first substrate and the second substrate perpendicularly cross each other.

In operation (f), a unit pixel of the LCD device may be defined to have four domains each having an alignment direction different from each other.

In operation (f), the liquid crystal may be a twisted-nematic (TN) mode.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein;

FIG. 1A is a schematic cross-sectional view showing a method of manufacturing an alignment substrate on which multiple alignment films are formed, in accordance with an embodiment of the present invention;

FIG. 1B is a schematic cross-sectional view showing a method of manufacturing an alignment substrate on which multiple alignment films are formed, in accordance with the embodiment of the present invention;

FIG. 1C is a schematic cross-sectional view showing a method of manufacturing an alignment substrate on which multiple alignment films are formed, in accordance with the embodiment of the present invention;

FIG. 1D is a perspective view showing a method of manufacturing an alignment substrate on which multiple alignment films are formed, in accordance with the embodiment of the present invention;

FIGS. 2A and 2B are schematic perspective views illustrating a unit pixel of a multi-domain liquid crystal display (LCD) device having the first alignment substrate manufactured in accordance with the method described with reference to FIGS. 1A through 1D;

FIGS. 3A through 3F illustrate experimental observation results of the behavior of liquid crystal of an LCD device by applying voltages to the LCD device having the alignment substrates manufactured in accordance with the method described with reference to FIGS. 1A through 1D, obtained using an optical microscope;

FIG. 4A is a graph illustrating transmittance versus voltage applied to an LCD device having the alignment substrates manufactured in accordance with the method described with reference to FIGS. 1A through 1D;

FIG. 4B is a graph illustrating response time versus voltage applied to an LCD device having the alignment substrates manufactured in accordance with the method described with reference to FIGS. 1A through 1D;

FIG. 5 is a graph illustrating viewing characteristics of an LCD device having the alignment substrates manufactured by the method described with reference to FIGS. 1A through 1D;

FIG. 6A is a schematic cross-sectional view illustrating a method of manufacturing an alignment substrate on which multiple alignment films are formed, in accordance with another embodiment of the present invention;

FIG. 6B is a schematic cross-sectional view illustrating a method of manufacturing an alignment substrate on which multiple alignment films are formed, in accordance with the another embodiment of the present invention;

FIG. 6C is a schematic cross-sectional view illustrating a method of manufacturing an alignment substrate on which multiple alignment films are formed, in accordance with the another embodiment of the present invention;

FIG. 6D is a perspective schematic view illustrating a method of manufacturing an alignment substrate on which multiple alignment films are formed, in accordance with the another embodiment of the present invention; and

FIG. 7 is a flow chart illustrating procedural steps of a method of manufacturing a LCD display device in accordance with still another embodiment of the present invention.

### DETAILED DESCRIPTION OF THE INVENTION

The present invention will now be described more fully with reference to the accompanying drawings in which exemplary embodiments of the invention are shown.

In a liquid crystal display device, surfaces of the electrodes in contact with the liquid crystal material are treated so as to align the liquid crystal molecules in a particular direction. This treatment generally uses a thin polymer layer that is unidirectionally rubbed. The direction of the liquid crystal alignment is then defined by the direction of rubbing. Electrodes may be made of a transparent conductor called Indium Tin Oxide (ITO). Before applying an electric field to the electrodes, the orientations of the liquid crystal molecules within the liquid crystal material are determined by the alignment at the surfaces of electrodes. As an example, in a twisted nematic mode liquid crystal display device, the surface alignment directions at the two electrodes may be perpendicular to each other. Therefore, the liquid crystal molecules may arrange themselves in a helical structure, or twist.

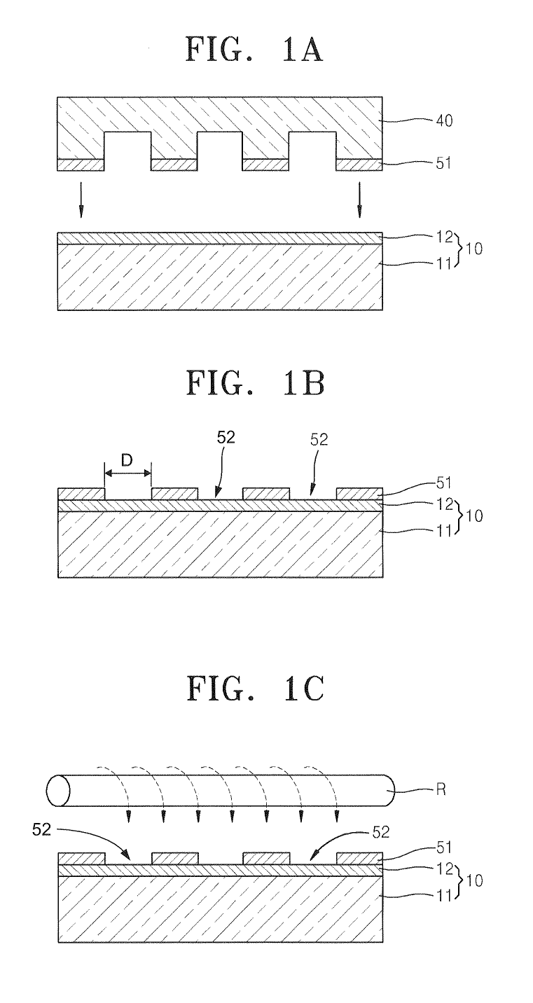

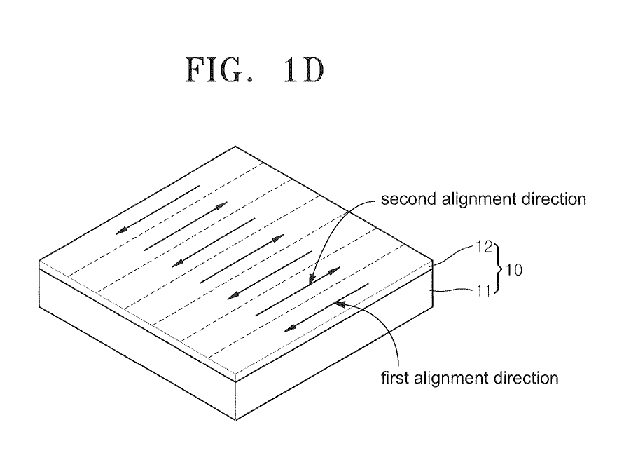

FIGS. 1A through 1D illustrate a method of manufacturing an alignment substrate on which multiple alignment films are formed, according to an embodiment of the present invention.

Referring to FIG. 1A, the first alignment substrate 10 includes a first substrate 11 and a first alignment film 12 aligned on the first substrate 11 in a first direction.

The first substrate 11 may be formed of a glass material or a plastic material, but is not limited thereto.

The first alignment film 12 is formed on the first substrate 11 to be aligned in the first direction. The first alignment film 12 may be oriented in the first direction by rubbing an organic polymer of a polyimide group or by using a photo-alignment process. The photo-alignment process is an alignment film processing method in which light is irradiated on a photosensitive thin film formed on the surface of a substrate to provide liquid crystal alignment.

After a stamping mold 40, on which fluoro-polymer patterns 51 are formed, is aligned onto the first alignment substrate 10, as shown in FIG. 1B, the fluoro-polymer patterns 51 are transferred onto the first alignment film 12.

The fluoro-polymer may be one of the materials shown Chemical formulae I through 3, and also, may be a functional substance containing 10-50% fluorine.

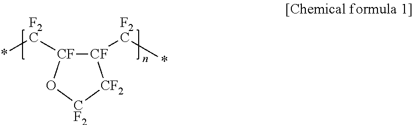

where n is an integer between 50 and 1000, i.e., 50≦n≦1000.

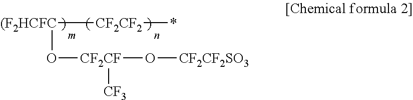

where m and n respectively are integers between 50 and 1000, i.e., 50≦n≦1000 and 50≦m≦1000.

*CF₂CF₂ₙ* [Chemical formula 3]

where n is an integer between 50 and 1000, i.e., 50≦n≦1000.

When the stamping mold 40 is removed from the fluoro-polymer patterns 51, since a solvent easily evaporates at room temperature, a subsequent process may be readily performed.

The stamping mold 40 may be a fine mold such as a polydimethysiloxane (PDMS) mold.

The PDMS mold may be formed to have a fine pattern of the stamping mold 40, such as a sub-pixel size corresponding to a domain of a multi-domain liquid crystal display device. Also, the stamping mold 40 may be formed to have fine patterns having various sizes and shapes. In the current embodiment, the stamping mold 40 may be formed so that the fluoro-polymer patterns 51 are disposed a predetermined distance D apart from each other.

Referring to FIG. 1C, a second alignment is performed on the first alignment film 12 on which the fluoro-polymer patterns 51 are formed.

In this case, the second alignment may be performed in an opposite direction (180 degrees) to the first alignment direction, but is not limited thereto. The second alignment may be performed in a second alignment direction which is different from the first direction of the first alignment.

The second alignment may be performed by a rubbing process using rubber R, but is not limited thereto. For example, the second alignment may be performed with a photo-alignment process.

The fluoro-polymer patterns 51 transferred onto the first alignment film 12 may function as a protective layer for protecting the first alignment film 12 during the second alignment process. Therefore, regions of the first alignment film 12 on which the fluoro-polymer patterns 51 are formed is not affected by the second alignment process. Accordingly, the alignment direction of the regions of the first alignment film 12 covered by the fluoro-polymer patterns 51 is not changed.

However, regions 52 of the first alignment film 12 on which the fluoro-polymer patterns 51 are not formed lose their initial alignment direction obtained by the first alignment process, and thus, maintain an alignment direction obtained from the second alignment process. The alignment direction of the regions 52 exposed by the fluoro-polymer patterns 51 may be changed by the second alignment process from the first alignment direction to the second alignment direction.

Next, the fluoro-polymer patterns 51 transferred onto the first alignment film 12 are removed by using a fluoro-solvent (not shown). As a result, as shown in FIG. 1D, the first alignment substrate 10 may be obtained, where the first alignment film 12 having multiple alignment directions is formed. In other words, the multiple alignment directions of the first alignment film 12 may be different from each other. As an example, two neighboring regions of the first alignment film 12 may have alignment directions opposite to each other (i.e., 180 degrees difference from each other).

In order to form an alignment substrate on which multiple alignment films are formed, an alignment process using a photoresist (PR) that is generally used to manufacture an inorganic semiconductor has been attempted. The alignment process using a PR is however complicated since such alignment process involves a photolithography process, and an alignment film may be physically or chemically damaged by a solvent used when the PR is coated or developed on the alignment film. Therefore, the characteristics of the alignment film may be degraded.

In order to prevent the problems described above, a photo-alignment process may be used. The photo-alignment process however has disadvantages, for example, a low anchoring problem and a reduction of the initial alignment characteristics over time, thereby reducing the reliability of an LCD device.

Halogen elements of Group 17 that includes fluorine have a characteristic of low reactivity with substances other than halogen elements. Thus, in the current embodiment, such characteristic of a fluorine group polymer and a fluorine group solvent may be used. Therefore, an alignment substrate on which a multiple alignment film is formed may be formed without having to involve a complicated process and the risk of damaging the alignment film.

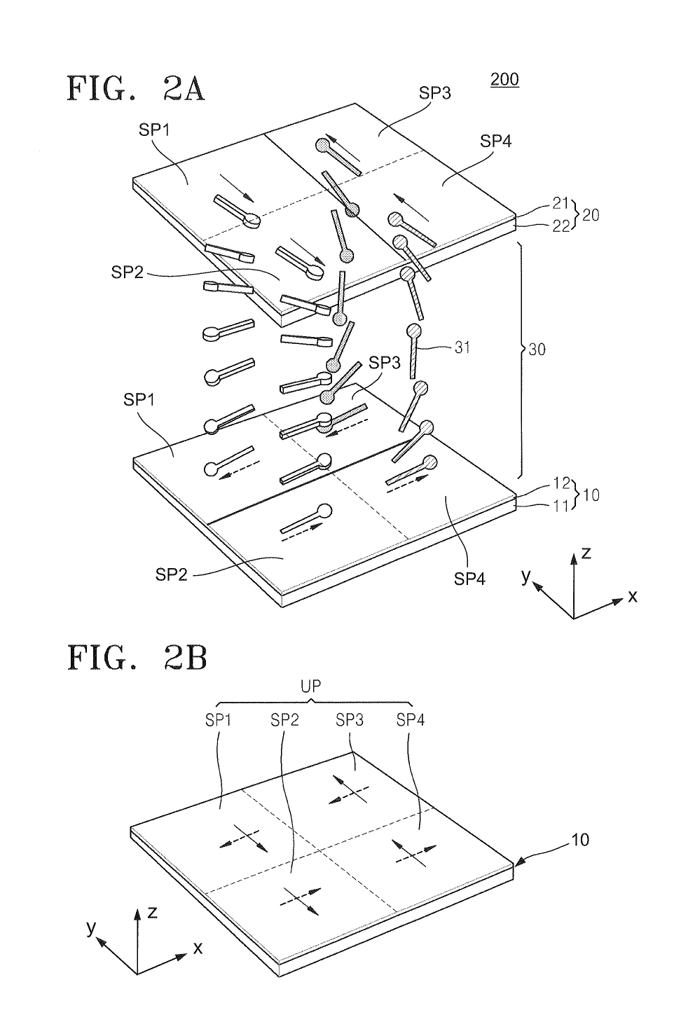

FIGS. 2A and 2B illustrate schematic perspective views of a unit pixel UP 200 of a multi-domain liquid crystal display (LCD) device having the first alignment substrate 10 manufactured according to the method described with reference to FIGS. 1A through 1D and having a second alignment substrate 20, according to an embodiment of the present invention.

The multi-domain LCD device includes the first alignment substrate 10 in which the first alignment film 12 is formed on a first substrate 11 and the second alignment substrate 20 in which a second alignment film 22 is formed on a second substrate 21, and a liquid crystal layer 30 interposed between the first alignment substrate 10 and the second alignment substrate 20.

In FIGS. 2A and 2B, the first and second alignment films 12 and 22 may be formed on the first and second alignment substrates 10 and 20, respectively. The first and second alignment substrates 10 and 20 may further include polarized films (not shown), pixel electrodes (not shown), and common electrodes (not shown), respectively. Also, the first and second alignment substrates 10 and 20 may further include thin film transistors (not shown), storage capacitors (not shown), and various wires, respectively.

As shown in FIG. 2A, after the first and second alignment substrates 10 and 20 are respectively manufactured according to the method described with reference to FIGS. 1A through 1D in order to have multiple alignment films having a first alignment direction x and a second alignment direction y different from the first alignment direction x, the first and second alignment substrates 10 and 20 are disposed so that the alignment direction of the first alignment substrate 10 perpendicularly crosses the alignment direction of the second alignment substrate 20.

As shown in FIG. 2B, the unit pixel UP 100 may be defined to have four domains having alignment directions different from each other. Here, the four domains may be formed to correspond to four sub-pixels SP1, SP2, SP3, and SP4.

In FIGS. 2A and 2B, the unit pixel UP includes four domains, the present invention is however not limited thereto. That is, when an additional alignment process is performed, the multiple alignment characteristic of the unit pixel UP may be increased to eight domains or more.

As shown in FIG. 2A, in each of four sub-pixels SP1, SP2, SP3, and SP4, the liquid crystal molecules 31 disposed within the liquid crystal layer 30 along coordinate Z gradually alter their orientations from a first direction to a second direction, where the first direction may be the alignment direction of the first alignment substrate 10 and the second direction may be the alignment direction of the second alignment substrate 20.

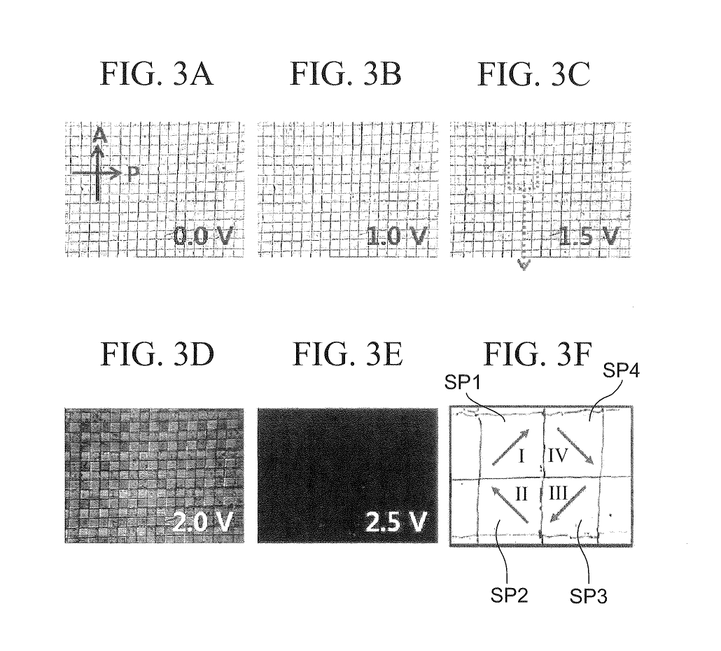

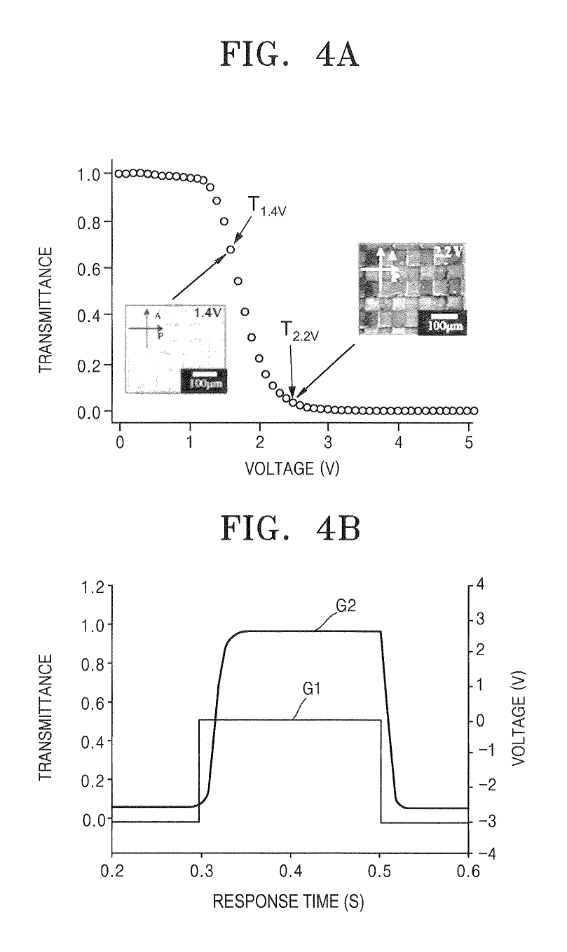

FIGS. 3A through 3F illustrate experimental observation results of the behavior of liquid crystal from applying voltages to an LCD device having the alignment substrates manufactured according to the method described with reference to FIGS. 1A through 1D, obtained by using an optical microscope. A and P coordinates of FIGS. 3A and 4A indicate polarization directions of upper and lower polarization plates that are disposed perpendicular to each other. The upper and lower polarization plates are arranged at boundaries of the first and second alignment substrates 10 and 20 in parallel to the first and second alignment substrates 10 and 20.

In the experiments, the alignment direction of the first alignment substrate 10 is disposed to perpendicularly cross the alignment direction of the second alignment substrate 20 as shown in FIG. 2A.

As shown in FIGS. 3A and 3D, when the voltage applied to the LCD device is increased from 0.0V to 2.0V, the brightness state of the LCD device gradually changes from an initial bright state to a black state. As shown in FIGS. 3B and 3E, when the voltage to the LCD device is increased from 1.0V to 2.5V, the brightness state of the LCD device gradually changes from an initial bright state to a black state.

FIG. 3F is a magnified partial portion of FIG. 3C. Referring to a magnified photo of FIG. 3F, the four domain regions SP1, SP2, SP3 and SP4 have liquid crystal alignment characteristics that are different from each other, and inclined lines I, II, III, and IV may respectively indicate the four different liquid crystal alignment characteristics of the four different domain regions SP1, SP2, SP3 and SP4.

FIG. 4A illustrates a graph of transmittance versus voltage applied to an LCD device having the alignment substrates manufactured according to the method described with reference to FIGS. 1A through 1D. FIG. 4B illustrates a graph of voltage vs. response time of an LCD device having the alignment substrates manufactured according to the method described with references to FIGS. 1A through 1D.

FIG. 4A shows detailed experimental observation results of FIGS. 3A through 3F, that is, observation results of the behaviour of liquid crystal, by applying voltages from 0V to 5V with an interval of 0.1V. FIG. 4A shows a normalized transmittance with respect to voltages applied to the LCD device. As shown in FIG. 4A, at point T_{1.4V}, 1.4V is applied to the LCD device, and the LCD device has a bright state where more light may be transmitted by the liquid crystal; at point T_{2.2V}, 2.2V is applied to the LCD device, and the LCD device has a black state where much less light may be transmitted by the liquid crystal.

From FIG. 4B, it is confirmed that the response time characteristic of liquid crystal according to a voltage applied to the LCD device is not much different from that of a contemporary single alignment device. Curve G1 shows the relation between the applied voltage and the response time, and Curve G2 shows the relation between the transmittance and the response time.

Therefore, the electro-optical characteristic of a multiple domain LCD device having the multiple alignment substrate manufactured according to the present invention is not disadvantageously reduced.

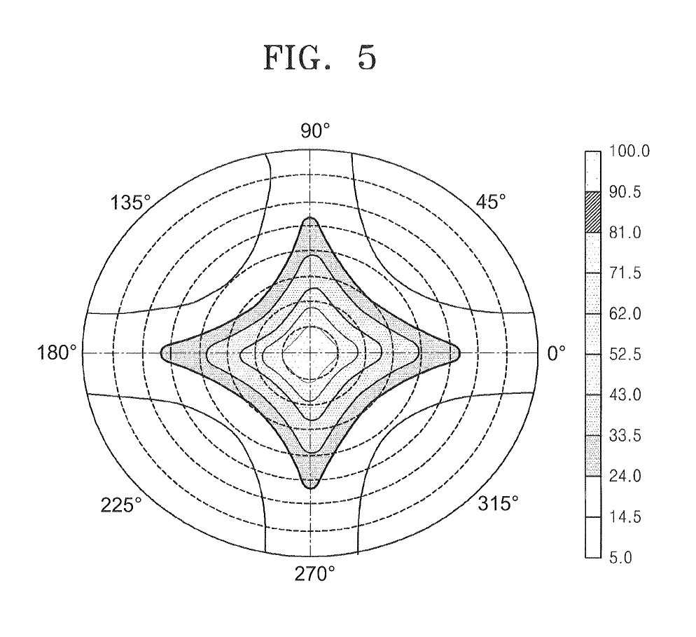

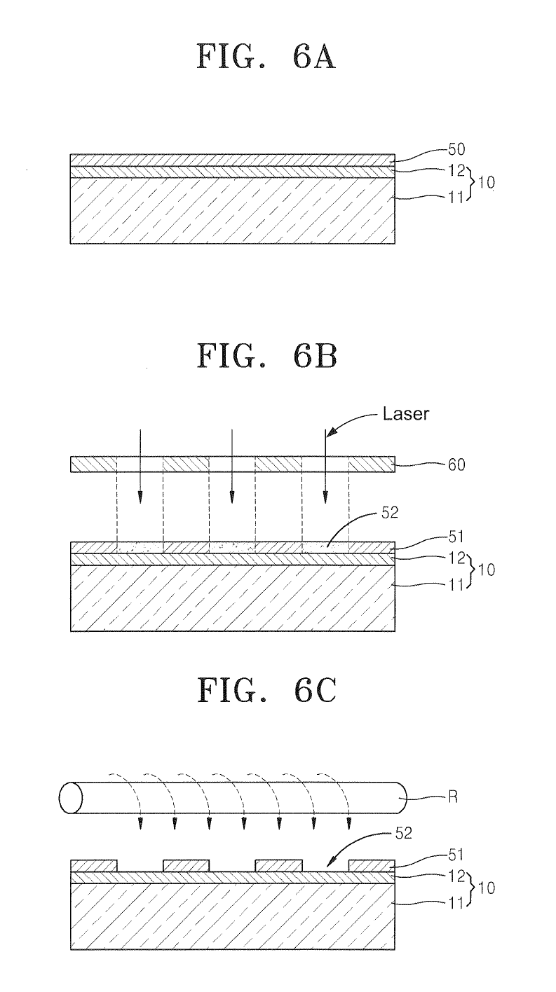

FIG. 5 illustrates a graph of the viewing characteristic of an LCD device having the alignment substrates manufactured according to the method described with reference to FIGS. 1A through 1D.

Referring to FIG. 5, compared to that of an LCD device having an alignment film aligned in a contemporary single alignment direction, the LCD device having an alignment substrate according to the present invention advantageously has a viewing angle that is not biased on one side. Also, the LCD device having an alignment substrate according to the present invention has a contrast ratio that is the same as that of the LCD device having an alignment film aligned in a contemporary single alignment direction.

That is, a multi-domain LCD device having an alignment substrate according to the present invention, as described above, has a wide viewing angle and a high contrast ratio, and may be manufactured with a simpler manufacturing process.

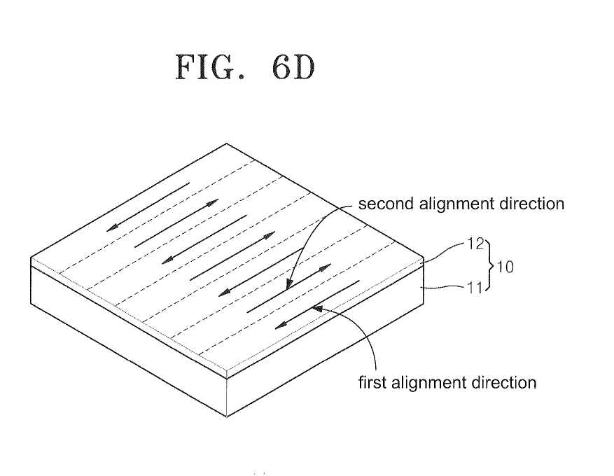

FIGS. 6A through 6D illustrate a method of manufacturing an alignment substrate on which multiple alignment films are formed, according to another embodiment of the present invention.

Referring to FIG. 6A, in the current embodiment, a fluoro-polymer layer 50 is directly formed on the first alignment film 12 to be aligned in a first direction. Unlike in the previous embodiment, fluoro-polymer patterns 51 in the current embodiment are not transferred onto a first alignment film 12 by using a stamping mold 40. The fluoro-polymer layer 50 may be formed by using a dip coating method or a spin coating method.

When the fluoro-polymer layer 50 is formed in a fluoro-solvent (not shown) having a low boiling point, the fluoro-polymer layer 50 having a uniform thickness from a few nanometers (nm) to a few micrometers (μm) may be formed.

Referring to FIG. 6B, fluoro-polymer patterns 51 are formed by selectively ablating the fluoro-polymer layer 50 by irradiating a laser onto the fluoro-polymer layer 50. Here, a mask 60 having a predetermined pattern may be used and the laser may be an excimer laser.

Referring to FIG. 6C, similar to the previous embodiment, a second alignment is performed on the first alignment film 12 on which the fluoro-polymer patterns 51 are formed, by using a rubbing process R.

At this point, the fluoro-polymer patterns 51 formed on the first alignment film 12 function as a protective layer for protecting the first alignment film 12 from the second alignment process. Therefore, the alignment direction of the first alignment film 12 covered by the fluoro-polymer patterns 51 is maintained.

Regions 52 of the first alignment film 12 on which the fluoro-polymer patterns 51 are not formed, however, lose their initial alignment direction. Therefore, the alignment direction of the regions 52 is changed due to the second alignment process.

Next, the fluoro-polymer patterns 51 are removed by using a fluoro-solvent (not shown). As a result, as shown in FIG. 6D, the first alignment substrate 10 on which the first alignment film 12 having multiple alignment directions different from each other, that is, a multiple alignment film is formed, is obtained.

In the current embodiment, after the fluoro-polymer patterns 51 are formed on the first alignment film 12 on which an initial alignment is determined by using a laser ablating method and a subsequent alignment process is performed, a process of removing the fluoro-polymer patterns 51 by using a fluoro-solvent is performed. In the process of removing the fluoro-polymer patterns 51, an alignment substrate on which multiple alignment films are formed may be manufactured without having to involve an additional complicated process and the risk of damaging the alignment film.

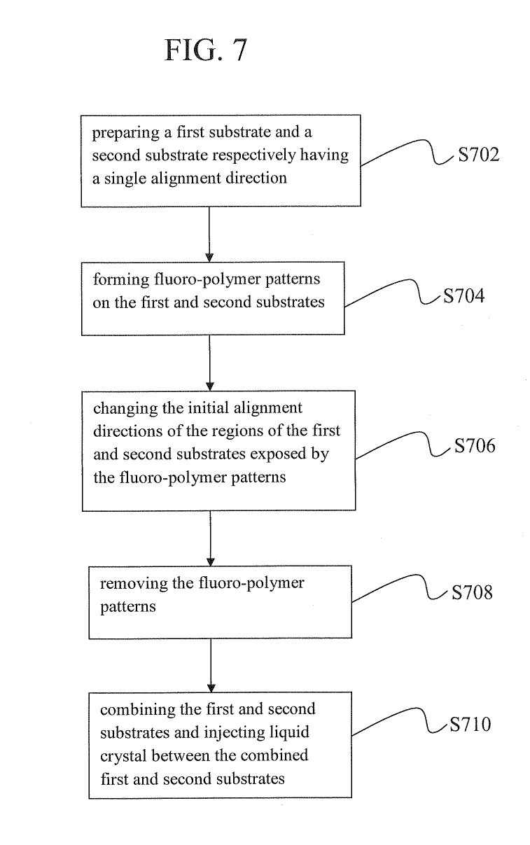

FIG. 7 is a flow chart illustrating the method of manufacturing a liquid crystal display device. In step S702, a first alignment substrate including a first alignment film and a second alignment substrate including a second alignment film respectively are prepared. Each of the alignment film has an initial alignment direction. In step S704, a plurality of fluoro-polymer patterns 51 are formed on the alignment films of the first and second alignment substrates. In step S706, the initial alignment directions of the regions of the first and second alignment films exposed by the fluoro-polymer patterns are changed. The changing of the initial alignment directions may be performed by a rubbing process using rubber R, but is not limited thereto. The changing of the initial alignment directions may be performed with a photo-alignment process. In step S708, the fluoro-polymer patterns may be removed by using a fluoro-solvent. In step S710, the first alignment substrate and the second alignment substrate are combined so that the alignment directions of the first alignment substrate and the second alignment substrate may cross each other, and liquid crystal is injected between the combined first and second alignment substrates. Due to the use of an alignment substrate and a method of manufacturing the alignment substrate according to the present invention, an alignment substrate on which multiple alignment films are formed may be manufactured without having to involve a complicated process and the risk of damaging the alignment films. Also, an LCD device having a wide viewing angle and high contrast ratio may be manufactured.

The scope of the present invention will be described in terms of essential processes and usable materials, and it will be understood by those of ordinary skill in the art that the concept and specific embodiments of the present invention may be used for performing purposes similar to the present invention. Also, the constituent elements in the drawings are enlarged or reduced for convenience of explanation. Therefore, the present invention is not limited to the sizes and shapes of the constituent elements in the drawings. It will also be understood by those of ordinary skill in the art that various changes and equivalent other embodiments may be made from the spirit and scope of the present invention. Therefore, the scope of the invention is defined not by the detailed description of the invention but by the appended claims.

What is claimed is:

1. A method of manufacturing an alignment substrate, the method comprising steps of:
preparing a first substrate on which an alignment film aligned in a first alignment direction is formed;
forming a plurality of fluoro-polymer patterns on the first substrate;
changing an alignment direction of regions of the alignment film exposed by the fluoro-polymer patterns; and
removing the plurality of fluoro-polymer patterns with a fluoro-solvent.

2. The method of claim 1, wherein, during the step of forming the plurality of fluoro-polymer patterns on the first substrate, the plurality of fluoro-polymer patterns are formed by transferring the plurality of fluoro-polymer patterns formed on a stamping mold onto the first substrate.

3. The method of claim 2, wherein the stamping mold is a polydimethysiloxane (PDMS) mold.

4. The method of claim 1, wherein, during the step of forming the plurality of fluoro-polymer patterns on the first substrate, the fluoro-polymer patterns are formed on the first substrate by performing a laser ablating method on a fluoro-polymer layer formed on the first substrate.

5. The method of claim 4, wherein the laser is an excimer laser.

6. The method of claim 1, wherein, during the step of forming the plurality of fluoro-polymer patterns on the first substrate, the fluoro-polymer patterns are spaced apart from each other by a predetermined distance.

7. The method of claim 1, wherein, during the step of changing the alignment direction of regions of the alignment film exposed by the fluoro-polymer patterns, the alignment of the regions of the alignment film exposed by the fluoro-polymer patterns is changed from the first alignment direction to a second alignment direction diametrically opposite to the first alignment direction.

8. The method of claim 7, wherein, during the step of changing the alignment direction of regions of the alignment film exposed by the fluoro-polymer patterns, the alignment film aligned in the first alignment direction has the same area as the alignment film aligned in the second alignment direction.

9. The method of claim 1, wherein, during the step of changing the alignment direction of regions of the alignment film exposed by the fluoro-polymer patterns, the alignment direction of the alignment film is changed by rubbing the regions of the alignment film exposed by the fluoro-polymer patterns.

10. The method of claim 1, wherein, during the step of changing the alignment direction of regions of the alignment film exposed by the fluoro-polymer patterns, the alignment direction of the alignment film is changed by using a photo-alignment method.

11. A method of manufacturing a liquid crystal display (LCD) device, the method comprising steps of:
preparing a first substrate and a second substrate each including an alignment film aligned in an initial alignment direction;
forming a plurality of fluoro-polymer patterns on each of the first and second substrates;
changing an alignment direction of regions of each alignment film exposed by the plurality of fluoro-polymer patterns;
removing the plurality of fluoro-polymer patterns with a fluoro-solvent; and
combining the first substrate and the second substrate, with alignment directions of the alignment film included in the first substrate and alignment directions of the alignment film included in the second substrate crossing each other, and injecting liquid crystal between the first substrate and the second substrate.

12. The method of claim 11, wherein, during the step of forming the plurality of fluoro-polymer patterns on each of the first and second substrates, the plurality of fluoro-polymer patterns are formed by transferring the plurality of fluoro-polymer patterns formed on a stamping mold onto the first substrate and the second substrate.

13. The method of claim 12, wherein the stamping mold is a polydimethysiloxane (PDMS) mold.

14. The method of claim 11, wherein, during the step of forming the plurality of fluoro-polymer patterns on each of the first and second substrates, the plurality of fluoro-polymer patterns are formed on the first substrate and the second substrate by ablating first and second fluoro-polymer layers respectively formed on the first substrate and the second substrate with a laser.

15. The method of claim 11, wherein, during the step of forming the plurality of fluoro-polymer patterns on each of the first and second substrates, the plurality of fluoro-polymer patterns are spaced apart from each other by a predetermined distance.

16. The method of claim 11, wherein, during the step of changing the alignment direction of regions of each alignment film exposed by the plurality of fluoro-polymer patterns, the alignment direction of each alignment film exposed by the plurality of fluoro-polymer patterns is changed to an alignment direction opposite to the initial alignment direction.

17. The method of claim 16, wherein, during the step of changing the alignment direction of regions of each alignment film exposed by the plurality of fluoro-polymer patterns, portions of each alignment film aligned in the initial alignment direction have the same area as portions of each alignment film aligned in the alignment direction opposite to the initial alignment direction.

18. The method of claim 11, wherein, during the step of changing the alignment direction of regions of each alignment film exposed by the plurality of fluoro-polymer patterns, the alignment direction of each alignment film is changed by rubbing the regions of each alignment film exposed by the plurality of fluoro-polymer patterns.

19. The method of claim 11, further comprised of applying a photo-alignment technique to change the alignment direction of regions of each alignment film exposed by the plurality of fluoro-polymer patterns.

20. The method of claim 11, wherein, during the steps of combining the first substrate and the second substrate and injecting the liquid crystal between the first substrate and the second substrate, alignment directions of the first substrate and alignment directions of the second substrate perpendicularly cross each other.

21. The method of claim 11, wherein, during the steps of combining the first substrate and the second substrate and injecting the liquid crystal between the first substrate and the second substrate, a unit pixel of the LCD device is defined to have four domains each having a unique alignment direction.

22. The method of claim 11, wherein, during the steps of combining the first substrate and the second substrate and injecting liquid crystal and injecting the liquid crystal between the first substrate and the second substrate, the liquid crystal is in a twisted-nematic (TN) mode.
